(19) United States
(12) Patent Application Publication
(10) Pub. No.: US 2008/0049875 A1
(43) Pub. Date: Feb. 28, 2008

(54) INTEGRATED TUNER APPARATUS, SYSTEMS, AND METHODS

(76) Inventors: Nick Cowley, Wroughton (GB); David Albert Sawyer, Swindon (GB); Isaac Ali, Bristol (GB)

Correspondence Address: SCHWEGMAN, LUNDBERG & WOESSNER, P.A., P.O. BOX 2938, MINNEAPOLIS, MN, 55402, US

(21) Appl. No.: 11/467,390

(22) Filed: Aug. 25, 2006

(51) Int. Cl. H03D 3/00

(52) U.S. Cl. 375/322

(57) ABSTRACT

Embodiments of a zero intermediate frequency (ZIF) tuner are described generally herein. Other embodiments may be described and claimed.

### TECHNICAL FIELD

Various embodiments described herein relate to electronic communications generally, including apparatus, systems, and methods associated with radio-frequency (RF) tuners.

### BACKGROUND INFORMATION

Traditional tuners may be used to receive terrestrial or cable broadcast signals in the range of about 50 megahertz (MHz) to 860 MHz. Such tuners may employ single conversion or double conversion intermediate frequency (IF) technology. A single conversion tuner may mix a received RF signal with a local oscillator (LO) signal in a single mixing stage to produce an IF signal. A common IF frequency may be about 36 MHz, for example.

A double conversion receiver may utilize two mixing stages to convert the received RF signal to the IF signal. A first stage may up-convert the received RF signal to a high-IF signal. The high-IF signal may be of a frequency greater than a maximum frequency of the received RF signal. A second mixing stage may then convert the high-IF signal to an output IF signal. The output IF signal may be of a frequency of about 36 MHz, for example.

In both the single conversion case and the double conversion case, an output IF stage may comprise a fixed-frequency channel filter and a variable gain IF amplifier. The fixed-frequency channel filter may comprise a surface acoustic wave (SAW) filter, among other types of filters. The output IF stage may be connected to a demodulator.

The terrestrial or cable broadcast signals may be analog modulated or digitally modulated. In the case of analog modulation, the SAW filter may be compatible with a quasi-split sound (QSS) demodulation scheme or with a vision IF (VIF) demodulation scheme. A QSS demodulator may require video and sound information to be separated in an IF domain. The IF signal may be split in a common SAW filter which provides two separated outputs. Alternatively, the IF signal may be filtered in two parallel SAW filters.

A VIF demodulator may process the entire video signal. A SAW filter associated with a VIF stage may shape the IF signal in a special way in order to appropriately attenuate sound information associated with the signal.

In both the QSS analog case and the VIF analog case, the IF SAW filter may apply asymmetric shaping. The asymmetric shaping may provide a Nyquist slope compatible with a vestigial sideband modulation mode associated with QSS and VIF. A digitally-modulated signal, on the other hand, may require a symmetrical IF SAW filter. Because of these differences in the IF stage necessitated by differing modulation standards, a receiver capable of multi-standard operation may necessarily duplicate the IF path, including the IF SAW filter. Semiconductor integration of the IF SAW filter may represent an additional challenge.

### BRIEF DESCRIPTION OF THE DRAWINGS

FIG. 1A is a block diagram of an apparatus and a representative system according to various embodiments.

FIG. 1B is a continuation of the block diagram of FIG. 1A.

FIG. 2A is a flow diagram illustrating several methods according to various embodiments.

FIG. 2B is a continuation of the flow diagram of FIG. 2A.

FIG. 3 is a block diagram of a computer-readable medium according to various embodiments.

### DETAILED DESCRIPTION

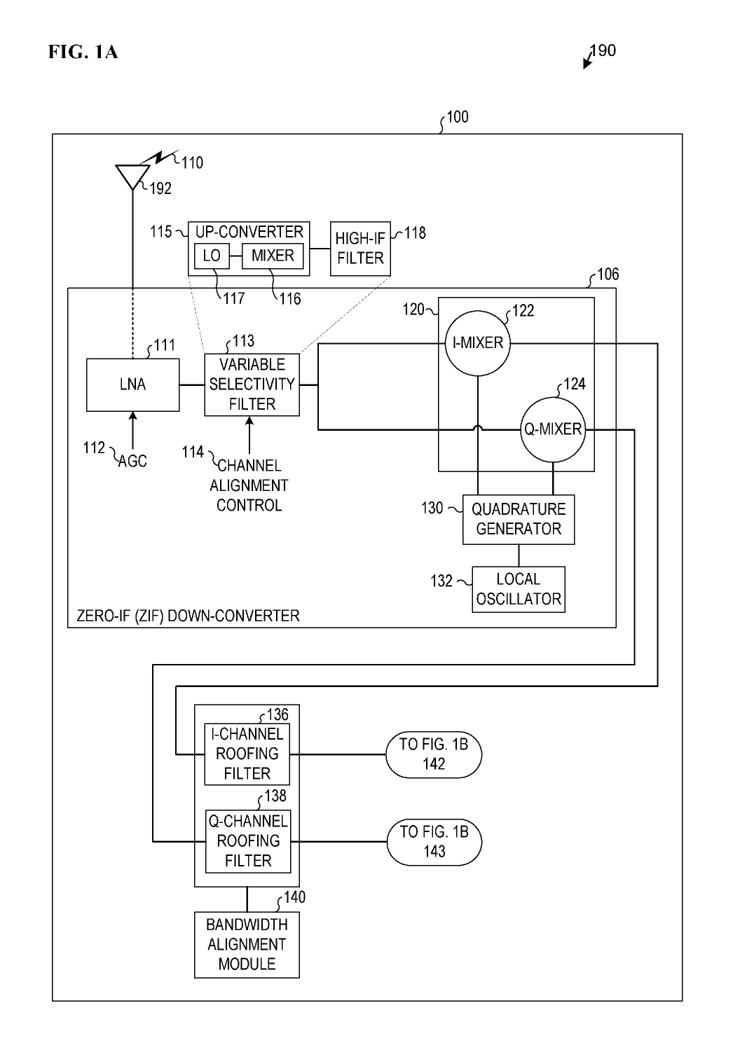

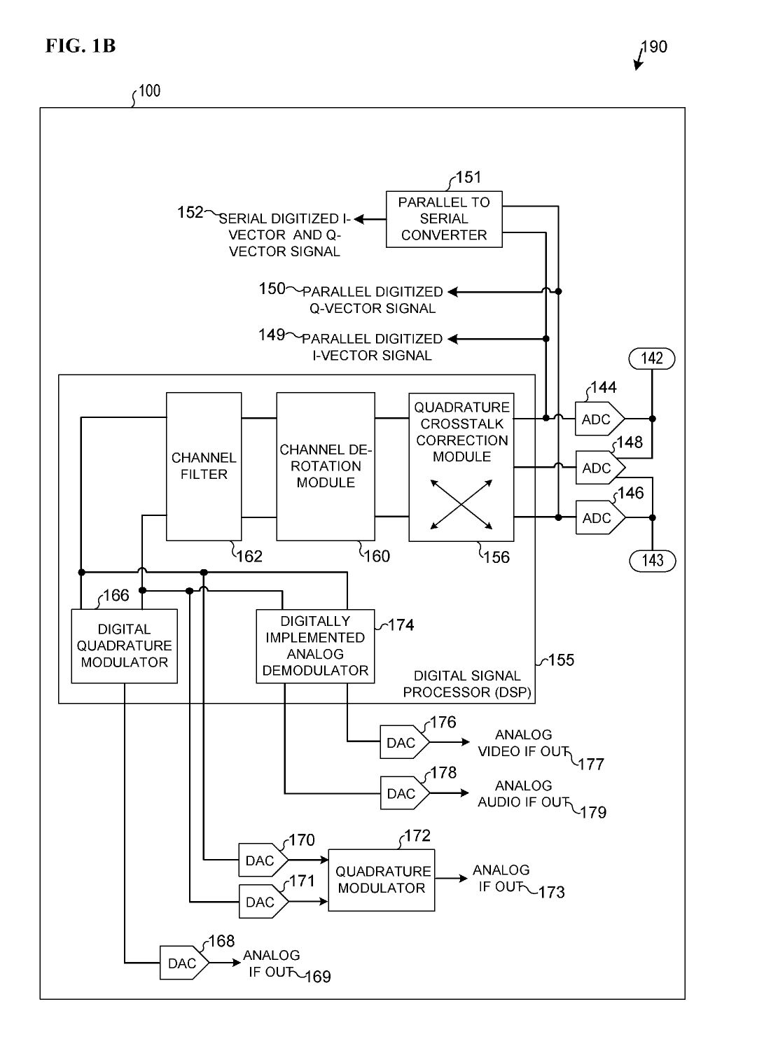

FIGS. 1A and 1B comprise a block diagram of an apparatus 100 and a system 190 according to various embodiments of the invention. A zero intermediate frequency (ZIF) conversion technique may be combined with digitally-controlled selectivity filtering and digital signal processor (DSP)-based signal impairment processing to yield a multi-standard tuner capable of semiconductor integration.

The apparatus 100 may comprise a ZIF down converter 106. The ZIF down converter 106 may perform a ZIF conversion operation on a received RF signal 110.

The ZIF down converter 106 may comprise a low-noise amplifier (LNA) stage 111. A gain associated with the LNA stage 111 may be capable of automatic control via an automatic gain control (AGC) signal 112 received from a subsequent stage. The ZIF down converter 106 may also comprise a variable selectivity filter 113. The variable selectivity filter 113 may be coupled to the LNA stage 111 to attenuate one or more interfering channels. A channel alignment control signal 114 may set a center frequency and/or a bandwidth of the variable selectivity filter 113.

In another embodiment, a dual-conversion tuner may include an up-converter 115 operatively coupled to the LNA stage 111 to produce a high-IF signal. The up-converter 115 may comprise a mixer 116 and a local oscillator 117. A high-IF filter 118 may be coupled to the up-converter 115 to filter unwanted signals following an up-conversion. The up-converter 115 and the high-IF filter 118 may be employed in the dual-conversion tuner in lieu of the variable selectivity filter 113 or in addition to the variable selectivity filter 113. In the latter case, the variable selectivity filter 113 may attenuate the one or more interfering channels prior to the up-conversion operation.

In some embodiments, a ZIF quadrature mixer 120 may be coupled to the high-IF filter 118. In some embodiments, the up-converter 115 may be tunable and the high-IF filter 118, the ZIF quadrature mixer 120, or both may be of a fixed frequency. In some embodiments, the up-converter 115 may be of a fixed frequency and the high-IF filter 118, the ZIF quadrature mixer 120, or both, may be tunable.

The ZIF quadrature mixer 120 may be coupled to the variable selectivity filter 113 or to the high-IF filter 118, as previously described. The ZIF quadrature mixer 120 may comprise an in-phase (I) mixer 122 and a quadrature-phase (Q) mixer 124. The I-mixer 122 and the Q-mixer 124 may quadrature-convert a desired channel signal to an I-vector signal component and a Q-vector signal component, respectively.

A quadrature generator 130 may be coupled to the I-mixer 122 and to the Q-mixer 124. The quadrature generator 130 may generate an in-phase LO signal for the I-mixer 122 and a quadrature-phase LO signal for the Q-mixer 124. An LO 132 may be coupled to the quadrature generator 130 to supply a base LO signal thereto.

An I-channel roofing filter 136 may be coupled to the I-mixer 122 to reduce a level of composite energy associated with the I-vector signal component. A Q-channel roofing filter 138 may be coupled to the Q-mixer 124 to reduce a level of composite energy associated with the Q-vector signal component. A bandwidth alignment module 140 may be coupled to the I-channel roofing filter 136, to the Q-channel roofing filter 138, or to both. The bandwidth alignment module 140 may adjust a cut-off frequency associated with the I-channel roofing filter, the Q-channel roofing filter, or both.

Turning to FIG. 1B, the apparatus 100 may also include a first analog-to-digital converter (ADC) 144. The first ADC 144 may be coupled to the I-channel roofing filter 136, at continuation block 142. The first ADC 144 may digitize the I-vector signal component. A second ADC 146 may be coupled to the Q-channel roofing filter 138, at continuation block 143. The second ADC 146 may digitize the Q-vector signal component. In some embodiments, a single ADC 148 may be coupled to both the I-channel roofing filter 136 and to the Q-channel roofing filter 138, in place of the first ADC 144 and the second ADC 146. The ADC 148 may digitize both the I-vector signal component and the Q-vector signal component. In the latter case, a dual sample-and-hold circuit (not shown) may be coupled to the ADC 148 to alternately sample the I-vector signal component and the Q-vector signal component, perhaps coincident with consecutive clock cycles.

In some embodiments, the digitized I-vector signal component may be output from the first ADC 144 or from the single ADC 148 in a parallel format, as a parallel digitized I-vector signal 149. Likewise, the digitized Q-vector signal component may be output from the second ADC 146 or from the single ADC 148 in a parallel format, as a parallel digitized Q-vector signal 150.

A parallel-to-serial converter 151 may convert the parallel digitized I-vector signal 149 and the parallel digitized Q-vector signal 150 to a serial digitized I-vector and Q-vector signal 152.

The apparatus 100 may further include a digital signal processor (DSP) 155 operatively coupled to the ZIF down converter 106. In some embodiments, the DSP 155 may be integrated on a common substrate with the ZIF down converter 106.

The DSP 155 may comprise a quadrature crosstalk correction module 156. The quadrature crosstalk correction module 156 may be coupled to the first ADC 144, to the second ADC 146, or to the single ADC 148. The quadrature crosstalk correction module 156 may remove undesirable artifacts resulting from the ZIF conversion operation. The undesirable artifacts may include phase spectral artifacts, gain spectral artifacts, or both. The undesirable artifacts may be carried on the digitized I-vector signal component, the digitized Q-vector signal component, or both.

The apparatus 100 may also include a channel de-rotation module 160. The channel de-rotation module 160 may be coupled to the quadrature crosstalk correction module 156. The channel de-rotation module 160 may remove a residual frequency component from the digitized I-vector signal component and from the digitized Q-vector signal component.

A channel filter 162 may be operatively coupled to the quadrature crosstalk correction module 156 to perform a filtering operation on the digitized I-vector signal component, the digitized Q-vector signal component, or both. The channel filter 162 may comprise a finite impulse response filter, among other types.

In some embodiments, the apparatus 100 may further comprise a digital quadrature modulator 166 coupled to the channel filter 162. The digital quadrature modulator 166 may recombine the digitized I-vector signal component and the digitized Q-vector signal component into a digital intermediate frequency (IF) signal. A digital-to-analog converter (DAC) 168 may be coupled to the digital quadrature modulator 166. The DAC 168 may convert the digital IF signal to a first analog IF output signal 169 capable of being demodulated using an external demodulator.

In some embodiments, the apparatus 100 may also include a first DAC 170 coupled to the channel filter. The first DAC 170 may convert the digitized I-vector signal to a processed analog I-vector signal. A second DAC 171 may also be coupled to the digital quadrature modulator. The second DAC 171 may convert the digitized Q-vector signal to a processed analog Q-vector signal. A quadrature modulator 172 may be coupled to the first DAC 170 and to the second DAC 171. The quadrature modulator 172 may quadrature-combine the processed analog I-vector signal and the processed analog Q-vector signal to yield a second analog IF output signal 173.

In some embodiments, the apparatus 100 may also include a digitally implemented analog demodulator 174 coupled to the channel filter 162. The digitally implemented analog demodulator 174 may demodulate a composite of the digitized I-vector signal component and the digitized Q-vector signal component to produce a digitized video IF signal and a digitized audio IF signal. A first DAC 176 may be coupled to the digitally implemented analog demodulator 174. The first DAC 176 may convert the digitized video IF signal to an analog video IF signal 177. A second DAC 178 may be coupled to the digitally implemented analog demodulator 174. The second DAC 178 may convert the digitized audio IF signal to an analog audio IF signal 179.

Turning back to FIG. 1A, in a further embodiment, a system 190 may include one or more of the apparatus 100. The system 190 may also include an antenna 192. The antenna 192 may comprise a patch antenna, a directional antenna, an omnidirectional antenna, a beam antenna, a slot antenna, a monopole antenna, or a dipole antenna, among other types. The antenna 192 may be coupled to the ZIF down-converter 106 to receive the RF signal 110.

Any of the components previously described may be implemented in a number of ways, including embodiments in software. Thus, the apparatus 100; the ZIF down converter 106; the signals 110, 112, 114, 149, 150, 152; the LNA stage 111; the variable selectivity filter 113; the up-converter 115; the mixers 116, 120, 122, 124; the LOs 117, 132; the high-IF filter 118; the quadrature generator 130; the roofing filters 136, 138; the bandwidth alignment module 140; the ADCs 144, 146, 148; the parallel-to-serial converter 151; the DSP 155; quadrature crosstalk correction module 156; the channel de-rotation module 160; the channel filter 162; the digital quadrature modulator 166; the DACs 168, 170, 171, 176, 178; the analog IF signals 169, 173, 177, 179; the quadrature modulator 172; the digitally implemented analog demodulator 174; the system 190; and the antenna 192 may all be characterized as “modules” herein.

The modules may include hardware circuitry, single or multi-processor circuits, memory circuits, software program modules and objects, firmware, and combinations thereof, as desired by the architect of the apparatus 100 and the system 190 and as appropriate for particular implementations of various embodiments.

The apparatus and systems of various embodiments may be useful in applications other than a multi-standard ZIF tuner capable of semiconductor integration. Thus, various embodiments of the invention are not to be so limited. The illustrations of the apparatus 100 and the system 190 are intended to provide a general understanding of the structure of various embodiments. They are not intended to serve as a complete description of all the elements and features of apparatus and systems that might make use of the structures described herein.

Applications that may include the novel apparatus and systems of various embodiments include electronic circuitry used in high-speed computers, communication and signal processing circuitry, modems, single or multi-processor modules, single or multiple embedded processors, multi-core processors, data switches, and application-specific modules, including multilayer, multi-chip modules. Such apparatus and systems may further be included as sub-components within a variety of electronic systems, such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others. Some embodiments may include a number of methods.

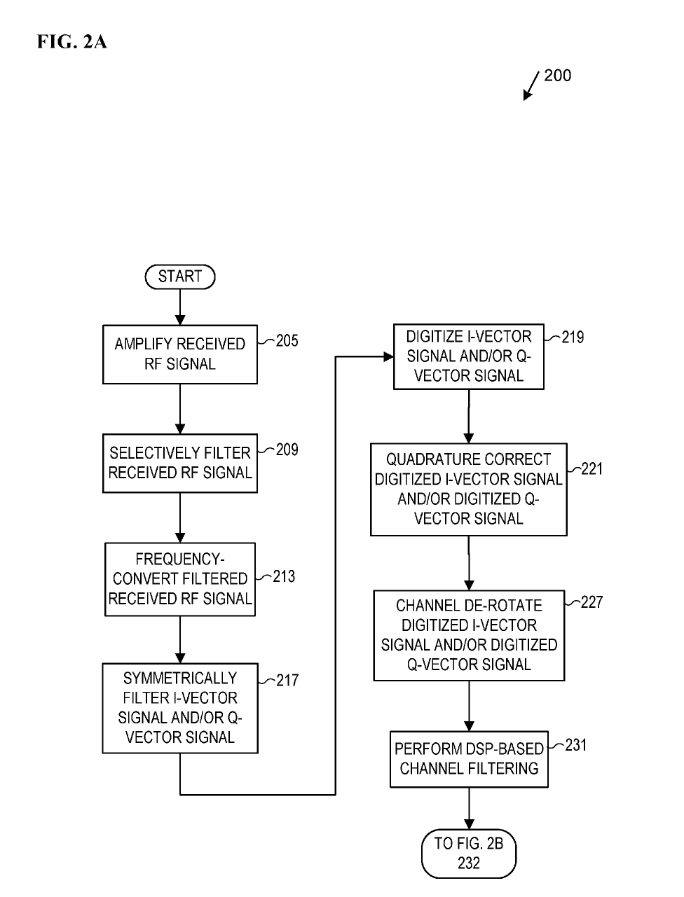

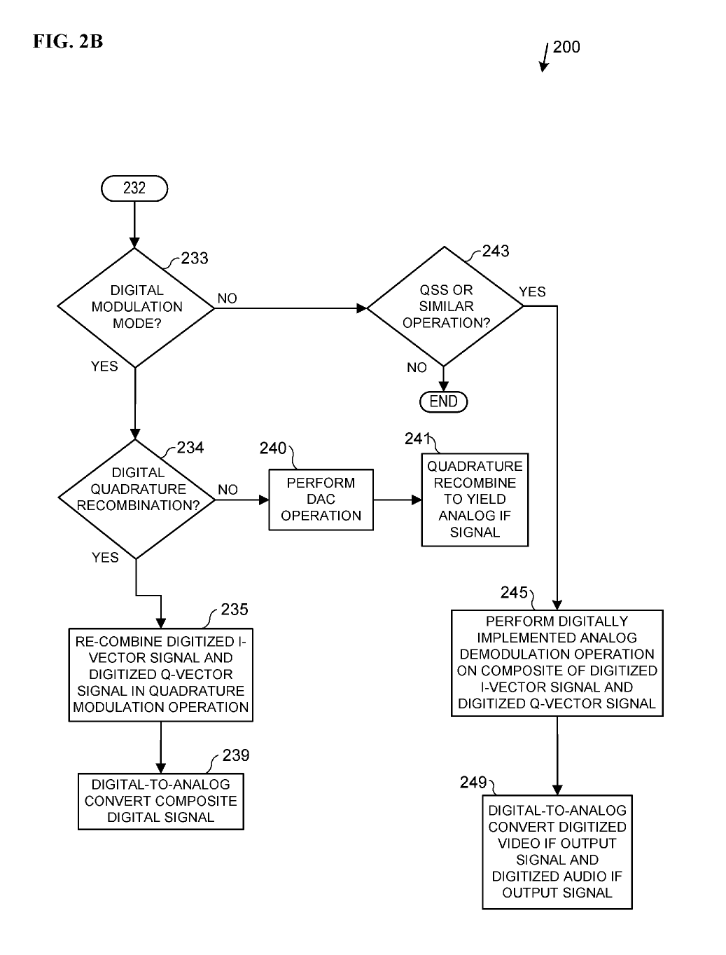

FIGS. 2A and 2B are a flow diagram illustrating several methods according to various embodiments. A method 200 may commence at block 205 with amplifying a received RF signal in an RF tuner according to an AGC signal fed back from a subsequent stage. The method 200 may continue at block 209 with selectively filtering the received RF signal. The received RF signal may be selectively filtered to remove one or more interfering channels prior to a frequency conversion process. A filtered received RF signal may result. The method 200 may continue further at block 213 with frequency converting the filtered received RF signal to a ZIF signal. The ZIF signal may comprise an I-vector signal and a Q-vector signal. In some embodiments, the frequency conversion process may operate to remove one or more interference components from a desired channel. Spectral energy in regions of third and fifth harmonic frequencies of the desired channel may be attenuated, for example.

The method 200 may include symmetrically filtering the I-vector signal, the Q-vector signal, or both, at block 217. The I-vector signal and/or the Q-vector signal may be symmetrically filtered to minimize quantization noise in a subsequent ADC stage. The quantization noise may be minimized by reducing a level of composite energy presented to the subsequent ADC stage.

The method 200 may also include performing an ADC operation on the I-vector signal to yield a digitized I-vector signal and/or on the Q-vector signal to yield a digitized Q-vector signal, at block 219. The method 200 may further include quadrature correcting the digitized I-vector signal, the digitized Q-vector signal, or both, at block 221. The digitized I-vector signal and the digitized Q-vector signal may be quadrature corrected to remove gain artifacts and/or phase artifacts. These artifacts may result from a quadrature imbalance introduced by a prior mixer stage or by a prior filter stage.

The method 200 may continue at block 227 with channel de-rotating the digitized I-vector signal, the digitized Q-vector signal, or both. The signal may be de-rotated to remove a frequency offset of the desired channel from a zero-frequency position. The method 200 may also include performing a DSP-based channel filtering operation on the digitized I-vector signal, the digitized Q-vector signal, or both, at block 231.

Turning to FIG. 2B, the method 200 may test to determine whether a digital modulation mode has been selected, at block 233. If so, the method 200 may further test to determine whether a quadrature recombination is desired in a digital domain or in an analog domain, at block 234. If the quadrature recombination is desired in the digital domain, the method 200 may include re-combining the digitized I-vector signal and the digitized Q-vector signal in a quadrature modulation operation, at block 235. The digitized I-vector signal and the digitized Q-vector signal may be re-combined to yield a composite digital signal. A digital-to-analog conversion operation may be performed on the composite digital signal to yield a first analog IF output signal, at block 239.

If the quadrature recombination is desired in the analog domain, the method 200 may include performing a digital to analog conversion operation on the digitized I-vector signal to yield a processed analog I-vector signal and on the digitized Q-vector signal to yield a processed analog Q-vector signal, at block 240. The method 200 may also include quadrature-combining the processed analog I-vector signal and the processed analog Q-vector signal to yield a second analog IF output signal, at block 241.

In some embodiments, the quadrature combining and digital-to-analog conversion operations may be capable of creating an analog IF output signal of a programmable IF frequency. Such embodiments may allow placement of the analog IF output signal at a frequency that is adaptable to a requirement of a subsequent IF stage.

Referring back to block 233, if digital modulation mode has not been selected, the method 200 may determine whether a QSS or similar mode of operation has been selected, at block 243. If so, the method 200 may also include performing a digitally implemented analog demodulation operation on a composite of the digitized I-vector signal and the digitized Q-vector signal, at block 245. The digitally implemented analog demodulation operation may yield a digitized video IF output signal and a digitized audio IF output signal. The method 200 may also include performing a digital-to-analog conversion operation on the digitized video IF output signal and on the digitized audio IF output signal, at block 249. An analog video IF output signal and an analog audio IF output signal may result.

It may be possible to execute the activities described herein in an order other than the order described. Further, various activities described with respect to the methods identified herein may be executed in repetitive, serial, or parallel fashion.

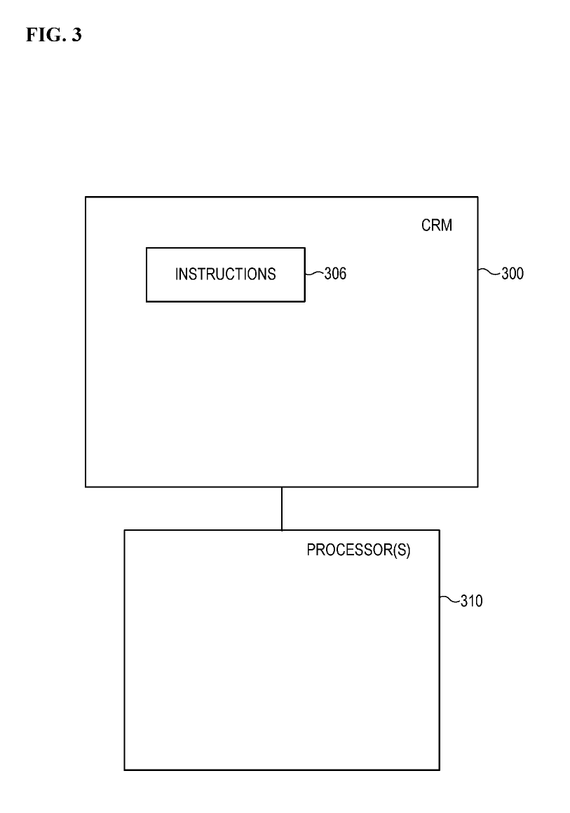

A software program may be launched from a computer-readable medium in a computer-based system to execute functions defined in the software program. Various programming languages may be employed to create software programs designed to implement and perform the methods disclosed herein. The programs may be structured in an object-orientated format using an object-oriented language such as Java or C++. Alternatively, the programs may be structured in a procedure-orientated format using a procedural language, such as assembly or C. The software components may communicate using a number of mechanisms well known to those skilled in the art, such as application program interfaces or inter-process communication techniques, including remote procedure calls. The teachings of various embodiments are not limited to any particular programming language or environment. Thus, other embodiments may be realized, as discussed regarding FIG. 3 below.

FIG. 3 is a block diagram of a computer readable medium (CRM) 300 according to various embodiments of the invention. Examples of such embodiments may comprise a memory system, a magnetic or optical disk, or some other storage device. The CRM 300 may contain instructions 306 which, when accessed, result in one or more processors 310 performing any of the activities previously described, including those discussed with respect to the method 200 noted above.

Implementing the apparatus, systems, and methods disclosed herein may exploit a ZIF conversion technique, digitally-controlled selectivity filtering, and DSP signal impairment processing to yield a multi-standard tuner capable of semiconductor integration.

Embodiments of the present invention may be implemented as part of a wired or wireless system. Examples may also include embodiments comprising multi-carrier wireless communication channels (e.g., orthogonal frequency division multiplexing (OFDM), discrete multitone (DMT), etc.) such as may be used within a wireless personal area network (WPAN), a wireless local area network (WLAN), a wireless metropolitan area network (WMAN), a wireless wide area network (WWAN), a cellular network, a third generation (3G) network, a fourth generation (4G) network, a universal mobile telephone system (UMTS), and like communication systems, without limitation.

The accompanying drawings that form a part hereof show, by way of illustration and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein individually or collectively by the term “invention” merely for convenience and without intending to voluntarily limit the scope of this application to any single invention or inventive concept, if more than one is in fact disclosed. Thus, although specific embodiments have been illustrated and described herein, any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

The Abstract of the Disclosure is provided to comply with 37 C.F.R. § 1.72(b), requiring an abstract that will allow the reader to quickly ascertain the nature of the technical disclosure. It is submitted with the understanding that it will not be used to interpret or limit the scope or meaning of the claims. In the foregoing Detailed Description, various features are grouped together in a single embodiment for the purpose of streamlining the disclosure. This method of disclosure is not to be interpreted to require more features than are expressly recited in each claim. Rather, inventive subject matter may be found in less than all features of a single disclosed embodiment. Thus the following claims are hereby incorporated into the Detailed Description, with each claim standing on its own as a separate embodiment.

What is claimed is:

1. An apparatus, including:
a zero intermediate frequency (ZIF) down converter to convert a received radio-frequency (RF) signal to a ZIF signal;
an in-phase (I) channel roofing filter coupled to the ZIF down converter to reduce a level of composite energy associated with an I-vector signal component of the ZIF down converter; and
a quadrature-phase (Q) channel roofing filter to reduce a level of composite energy associated with a Q-vector signal component of the ZIF down converter.

2. The apparatus of claim 1, further including:
a first analog-to-digital converter (ADC) coupled to the I-channel roofing filter to digitize the I-vector signal component to yield a parallel digitized I-vector signal, and
a second ADC coupled to the Q-channel roofing filter to digitize the Q-vector signal component to yield a parallel digitized Q-vector signal.

3. The apparatus of claim 2, further including:
a parallel-to-serial converter to convert the parallel digitized I-vector signal and the parallel digitized Q-vector signal to a serial digitized I-vector and Q-vector signal.

4. An apparatus, including:
a zero intermediate frequency (ZIF) down converter to convert a received radio-frequency (RF) signal to a ZIF signal; and
a digital signal processor (DSP) operatively coupled to the ZIF down converter to perform signal processing operations on the ZIF signal.

5. The apparatus of claim 4, wherein the DSP is integrated on a common substrate with the ZIF down converter.

6. The apparatus of claim 4, wherein the ZIF down converter comprises:
a low-noise amplifier (LNA) stage;
a variable selectivity filter coupled to the LNA stage to attenuate at least one interfering channel; and
a ZIF quadrature mixer coupled to the variable selectivity filter, the ZIF quadrature mixer comprising an in-phase (I) mixer to quadrature-convert a desired channel signal to an I-vector signal component and a quadrature-phase (Q) mixer to quadrature-convert a desired channel signal to a Q-vector signal component.

7. The apparatus of claim 6, wherein a gain associated with the LNA stage is capable of automatic control via an automatic gain control signal received from a subsequent stage.

8. The apparatus of claim 6, further including:
a quadrature generator coupled to the I mixer and to the Q mixer to generate an in-phase local oscillator (LO) signal for the I mixer and to generate a quadrature-phase LO signal for the Q-mixer; and
an LO coupled to the quadrature generator to supply a base LO signal to the quadrature generator.

9. The apparatus of claim 6, further including:
at least one of an I-channel roofing filter coupled to the I-mixer to reduce a level of composite energy associated with the I-vector signal component or a Q-channel roofing filter coupled to the Q-mixer to reduce a level of composite energy associated with the Q-vector signal component.

10. The apparatus of claim 6, further including:
a bandwidth alignment module coupled to the at least one of the I-channel roofing filter or the Q-channel roofing filter to adjust a cut-off frequency associated with the at least one of the I-channel roofing filter or the Q-channel roofing filter.

11. The apparatus of claim 9, further including at least one of:
a first analog-to-digital converter (ADC) coupled to the I-channel roofing filter to digitize the I-vector signal component and a second ADC coupled to the Q-channel roofing filter to digitize the Q-vector signal component; or
a single ADC coupled to the I-channel roofing filter and to the Q-channel roofing filter to digitize the I-vector signal component and the Q-vector signal component and a dual sample-and-hold circuit coupled to the ADC to alternately sample the I-vector signal component and the Q-vector signal component coincident with consecutive clock cycles.

12. The apparatus of claim 11, further including:
a quadrature crosstalk correction module coupled to at least one of the first ADC, the second ADC, or the single ADC to remove at least one of phase spectral artifacts resulting from the ZIF conversion operation or gain spectral artifacts resulting from the ZIF conversion operation from at least one of a digitized I-vector signal component or a digitized Q-vector signal component.

13. The apparatus of claim 12, further including:
a channel de-rotation module coupled to the quadrature crosstalk correction module to remove a residual frequency component from the digitized I-vector signal component and from the digitized Q-vector signal component.

14. The apparatus of claim 12, further including:
a channel filter operatively coupled to the quadrature crosstalk correction module to perform a filtering operation on at least one of the digitized I-vector signal component or the digitized Q-vector signal component.

15. The apparatus of claim 14, wherein the channel filter comprises a finite impulse response filter.

16. The apparatus of claim 14, further including:
a digital quadrature modulator coupled to the channel filter to recombine the digitized I-vector signal component and the digitized Q-vector signal component into a digital intermediate frequency (IF) signal; and
a digital-to-analog converter (DAC) coupled to the digital quadrature modulator to convert the digital IF signal to an analog IF signal.

17. The apparatus of claim 14, further including:
a first digital-to-analog converter (DAC) coupled to the channel filter to convert the digitized I-vector signal to a processed analog I-vector signal;
a second DAC coupled to the channel filter to convert the digitized Q-vector signal to a processed analog Q-vector signal; and
a quadrature modulator to quadrature-combine the processed analog I-vector signal and the processed analog Q-vector signal to yield an analog intermediate frequency output signal.

18. The apparatus of claim 14, further including:
a digitally implemented analog demodulator coupled to the channel filter to demodulate a composite of the digitized I-vector signal component and the digitized Q-vector signal component to produce a digitized video IF signal and a digitized audio IF signal; and
a first digital-to-analog converter (DAC) coupled to the digitally implemented analog demodulator to convert the digitized video IF signal to an analog video IF signal and a second DAC coupled to the digitally implemented analog demodulator to convert the digitized audio IF signal to an analog audio IF signal.

19. A system, including:
a zero intermediate frequency (ZIF) down converter to convert a received radio-frequency (RF) signal to a ZIF signal;
a digital signal processor (DSP) operatively coupled to the ZIF down converter to perform signal processing operations on the ZIF signal; and
a directional antenna coupled to the ZIF down-converter to receive the RF signal.

20. The system of claim 19, further including:
a low-noise amplifier (LNA) stage;
an up-converter operatively coupled to the LNA stage to produce a high-IF signal, the up-converter comprising a mixer and a local oscillator; and
a high-IF filter to filter unwanted signals following an up-conversion.

21. The system of claim 20, further including:
a variable selectivity filter coupled to the LNA stage to attenuate at least one interfering channel prior to an up-conversion operation.

22. The system of claim 20, further including:
a ZIF quadrature mixer coupled to the high-IF filter, the ZIF quadrature mixer comprising an in-phase (I) mixer to quadrature-convert a desired channel signal to an I-vector signal component and a quadrature-phase (Q) mixer to quadrature-convert a desired channel signal to a Q-vector signal component.

23. The system of claim 22, wherein the up-converter is tunable and at least one of the high-IF filter or the ZIF quadrature mixer is of a fixed frequency.

24. The system of claim 22, wherein the up-converter is of a fixed frequency and at least one of the high-IF filter or the ZIF quadrature mixer is tunable.

25. A method, including:
frequency converting a filtered received radio-frequency (RF) signal to a zero intermediate frequency (ZIF) signal comprising an in-phase (I) vector signal and a quadrature-phase (Q) vector signal; and
performing a digital signal processor (DSP)-based channel filtering operation on at least one of a digitized I-vector signal or a digitized Q-vector signal.

26. The method of claim 25, further including:
symmetrically filtering at least one of the I-vector signal or the Q-vector signal to minimize quantization noise in a subsequent analog-to-digital converter (ADC) stage by reducing a level of composite energy presented to the subsequent ADC stage.

27. The method of claim 26, further including:
performing an ADC operation on the I-vector signal to yield the digitized I-vector signal; and
performing an ADC operation on the Q-vector signal to yield the digitized Q-vector signal.

28. The method of claim 25, further including:
quadrature correcting at least one of the digitized I-vector signal or the digitized Q-vector signal to remove at least one of gain artifacts or phase artifacts resulting from a quadrature imbalance introduced by at least one of a prior mixer stage or a prior filter stage.

29. The method of claim 25, further including:
channel de-rotating at least one of the digitized I-vector signal or the digitized Q-vector signal to remove a frequency offset of the desired channel from a zero-frequency position.

30. The method of claim 25, further including:
re-combining the digitized I-vector signal and the digitized Q-vector signal in a quadrature modulation operation to yield a composite digital signal; and
performing a digital-to-analog conversion operation on the composite digital signal to yield an analog intermediate frequency output signal.

31. The method of claim 25, further including:
performing a digital to analog conversion operation on the digitized I-vector signal to yield a processed analog I-vector signal and on the digitized Q-vector signal to yield a processed analog Q-vector signal; and
quadrature-combining the processed analog I-vector signal and the processed analog Q-vector signal to yield an analog intermediate frequency output signal.

32. The method of claim 25, further including:
performing a digitally implemented demodulation operation on a composite of the digitized I-vector signal and the digitized Q-vector signal to yield a digitized video intermediate frequency (IF) output signal and a digitized audio IF output signal; and
performing a digital-to-analog conversion operation on the digitized video IF output signal and on the digitized audio IF output signal to yield an analog video IF output signal and an analog audio IF output signal.

33. An article including a machine-accessible medium having associated information, wherein the information, when accessed, results in a machine performing:
frequency converting a received radio-frequency (RF) signal associated with a desired channel to a zero intermediate frequency (ZIF) signal comprising an in-phase (I) vector signal and a quadrature-phase (Q) vector signal, wherein spectral energy in regions of third and fifth harmonic frequencies of the desired channel is attenuated; and
performing a digital signal processor (DSP)-based channel filtering operation on a version of the digitized I-vector signal and on a digitized version of the Q-vector signal.

34. The article of claim 33, wherein the information, when accessed, results in a machine performing:
selectively filtering the RF signal prior to a frequency conversion process to remove at least one interfering channel to yield a filtered received RF signal; and
within the frequency conversion process, removing at least one interference component harmonically related to the desired channel.

35. The article of claim 33, wherein the information, when accessed, results in a machine performing:
symmetrically filtering the I-vector signal or the Q-vector signal to minimize quantization noise in a subsequent analog-to-digital converter (ADC) stage by reducing a level of composite energy presented to the subsequent ADC stage.
